(19) United States
(12) Patent Application Publication
(10) Pub. No.: US 2023/0393303 A1
(43) Pub. Date: Dec. 7, 2023

(54) INTEGRATED DIAGENETIC-DEPOSITIONAL FACIES (IDDF) CHARACTERIZATION AND 3D GEOMODELING

(71) Applicant: Saudi Arabian Oil Company, Dhahran (SA)

(72) Inventor: Adam Danur Zeiza, Dhahran (SA)

(21) Appl. No.: 17/829,625

(22) Filed: Jun. 1, 2022

(51) Int. Cl. G01V 99/00; G06F 30/27

(52) U.S. Cl. CPC G01V 99/005; G06F 30/27

(57) ABSTRACT

Systems and methods include a computer-implemented method for suggesting changes in wellbore operations based on the reservoir quality predictions, three-dimensional (3D) reservoir modeling, and volume estimations. Correlated geoscience datasets are generated for a set of oil and gas drilling operations. Integrated Diagenetic-Depositional Facies (IDDF) classifications are performed using genetic and analytic criteria and using the correlated geoscience datasets. A training dataset is prepared using the IDDF classifications and well data including core, petrographic, and routine core analyses (RCA) data. The training dataset includes correlations of porosity-permeability (poro-perm) and log properties. Automated machine learning is performed using the training dataset to provide IDDF estimation in uncovered wells. Reservoir quality predictions, 3D reservoir modeling, and volume estimations are performed based on the automated machine learning. Suggested changes to make in wellbore operations are provided in a user interface based on the reservoir quality predictions, the 3D reservoir modeling, and the volume estimations.

### TECHNICAL FIELD

The present disclosure applies to determining reservoir quality, e.g., in oil fields.

### BACKGROUND

In most carbonate reservoirs, initial depositional characteristics and subsequent diagenetic modification processes are strongly associated with reservoir quality and heterogeneity. These processes are often inter-related and usually impact basic reservoir properties such as porosity, permeability, and water saturation. Information about these parameters are often generated by (or included in) logs such as density logs, neutron logs, sonic logs, and resistivity logs.

Many carbonate oil and gas fields typically suffer from inaccurate volumetric estimation, poor history matching, poor production forecast, and reservoir management. This can occur due to the lack of integrated reservoir characterization and three-dimensional (3D) geomodeling. One of the key elements of carbonate reservoir characterization that is often under-represented is diagenesis (e.g., including dissolutions, dolomitizations, and cementations). Diagenetic processes can be used in conjunction with pre-existing depositional products and in generating multi-scale pore systems, e.g., spanning from meter to micron size. In many carbonate fields, these multi-scale diagenetic components, their paragenesis, and their distribution within a 3D space are often poorly represented. These features may be blended into the terms of carbonate reservoir heterogeneity and complexity. As a result, reservoir properties may be modeled randomly (stochastically).

Many carbonate reservoirs are often under-characterized due to the absence of integrated diagenetic studies. In several cases, carbonate reservoir property models are just modeled using basic depositional (litho) facies as the basis for determining or estimating reservoir quality. This approach often fails to capture the full spectrum of carbonate reservoir heterogeneity, its predictability, and its volumetric impact.

### SUMMARY

The present disclosure describes techniques that can be used for Integrated Diagenetic-Depositional Facies (IDDF) characterization and three-dimensional (3D) geomodeling. In some implementations, a computer-implemented method includes the following. Correlated geoscience datasets are generated for a set of oil and gas drilling operations. Integrated Diagenetic-Depositional Facies (IDDF) classifications are performed using genetic and analytic criteria and using the correlated geoscience datasets. A training dataset is prepared using the IDDF classifications and well data including core, petrographic, and routine core analyses (RCA) data. The training dataset includes correlations of porosity-permeability (poro-perm) and log properties. Automated machine learning is performed using the training dataset to provide IDDF estimation in uncovered wells. Reservoir quality predictions, 3D reservoir modeling, and volume estimations are performed based on the automated machine learning. Suggested changes to make in wellbore operations are provided in a user interface based on the reservoir quality predictions, the 3D reservoir modeling, and the volume estimations.

The previously described implementation is implementable using a computer-implemented method; a non-transitory, computer-readable medium storing computer-readable instructions to perform the computer-implemented method; and a computer-implemented system including a computer memory interoperably coupled with a hardware processor configured to perform the computer-implemented method, the instructions stored on the non-transitory, computer-readable medium.

The subject matter described in this specification can be implemented in particular implementations, so as to realize one or more of the following advantages. The techniques of the present disclosure can be used to overcome limitations in carbonate oil and gas fields that experience poor up-side volumetric estimation, reservoir quality prediction, under-estimated volumetric assessment, and poor reservoir simulation history-matching. The limitations may exist due to the lack of data integration, characterization, and 3D geo-cellular modeling of geo-bodies and the associated properties. As described in the present disclosure, an integrated workflow can be used that provides a comprehensive method to characterize and model the 3D integrated depositional and diagenetic facies (IDDF) distribution and associated porosity, permeability, and water saturation. Limitations in conventional systems related to IDDF property modeling can be overcome by integrating both static and dynamic data early in 3D geo-cellular modeling processed. IDDF workflows improve the integration of multi-disciplinary data sets such as geology (e.g., petrography, diagenetic concepts), geophysics (e.g., seismic attributes), and reservoir engineering data (e.g., production flow meter log). This integration allows a more comprehensive workflow to build both 3D static (geologic) and dynamic (simulation) models than the traditional modeling workflow. This in turn generates a more robust 3D subsurface description for better hydrocarbon volume estimation, well placement, fluid dynamic simulation and production forecasting.

The details of one or more implementations of the subject matter of this specification are set forth in the Detailed Description, the accompanying drawings, and the claims. Other features, aspects, and advantages of the subject matter will become apparent from the Detailed Description, the claims, and the accompanying drawings.

### DESCRIPTION OF DRAWINGS

FIG. 1 is a flow chart showing an example of a workflow for integrated diagenetic-depositional facies (IDDF) characterization and three-dimensional (3D) geomodeling, according to some implementations of the present disclosure.

FIG. 2 is a block diagram showing an example workflow for well data preparation, integration, and machine learning estimation of the IDDF, according to some implementations of the present disclosure.

FIG. 3 is a block diagram showing an example of an IDDF classification using the integration of petrography and routine core analyses, according to some implementations of the present disclosure.

FIG. 4 is a flow diagram showing an example integration of seismic data, well logs, flow meter data, and the IDDF flags at well location, according to some implementations of the present disclosure.

FIG. 5 is a flow diagram showing an example of 3D IDDF modeling using an integration of seismic and well data, according to some implementations of the present disclosure.

FIG. 6 is a flowchart of an example of a method for determining reservoir quality, according to some implementations of the present disclosure.

FIG. 7 is a block diagram illustrating an example computer system used to provide computational functionalities associated with described algorithms, methods, functions, processes, flows, and procedures as described in the present disclosure, according to some implementations of the present disclosure.

Like reference numbers and designations in the various drawings indicate like elements.

### DETAILED DESCRIPTION

The following detailed description describes techniques for Integrated Diagenetic-Depositional Facies (IDDF) characterization and three-dimensional (3D) geomodeling. Various modifications, alterations, and permutations of the disclosed implementations can be made and will be readily apparent to those of ordinary skill in the art, and the general principles defined may be applied to other implementations and applications, without departing from the scope of the disclosure. In some instances, details unnecessary to obtain an understanding of the described subject matter may be omitted so as to not obscure one or more described implementations with unnecessary detail and inasmuch as such details are within the skill of one of ordinary skill in the art. The present disclosure is not intended to be limited to the described or illustrated implementations, but to be accorded the widest scope consistent with the described principles and features.

The workflow of the present disclosure integrates both depositional and diagenetic aspects to model reservoir properties in a practical way, using a multi-disciplinary dataset (e.g., petrographic, petrophysical, geophysical, and dynamic data). This approach not only improves 3D reservoir properties distribution (e.g., porosity and permeability) but also optimizes up-side volumetrics, development well placement, history-matching, and hydrocarbon production forecasting. For example, optimizing in this sense can refer to achieving output values of the model that indicate or result in a performance and a volume greater than a predefined threshold, or result in estimates that match or correlate with real-world conditions within a pre-determined percentage.

The workflow of the present disclosure can be used for characterizing and modeling integrated diagenetic-depositional facies (IDDF s) in carbonate reservoirs, from one-dimensional (1D) IDDF classification and neural network estimation, to two-dimensional (2D) IDDF trend and seismic-based probability region modeling, and culminating with 3D geo-cellular modeling processes. Being able to blend the carbonate reservoir classification, estimation, and modeling utilizing an IDDF scheme can provide a valuable tool in characterizing diagenetically complex carbonates. This can provide the benefit of constructing a geologically-consistent 3D reservoir model that can be greatly beneficial during simulations.

The workflow of the present disclosure can include the use of multi-disciplinary datasets and analyses and the integration of a number of geoscience datasets including (but not restricted to) a linking of petrographic thin section analyses with other scales of data from core descriptions, well-logs signatures and interpretation, routine core analyses (RCA), borehole image logs interpretation, production logging tool (PLT) flow meter signals, diagenetic proxies, and depositional concepts. Steps of the workflow can associate these features with 3D seismic attribute region extraction for the benefit of 3D geo-cellular property modeling. This can greatly improve reservoir quality prediction, 3D reservoir modeling, volume estimation, history-matching processes, and production forecasts.

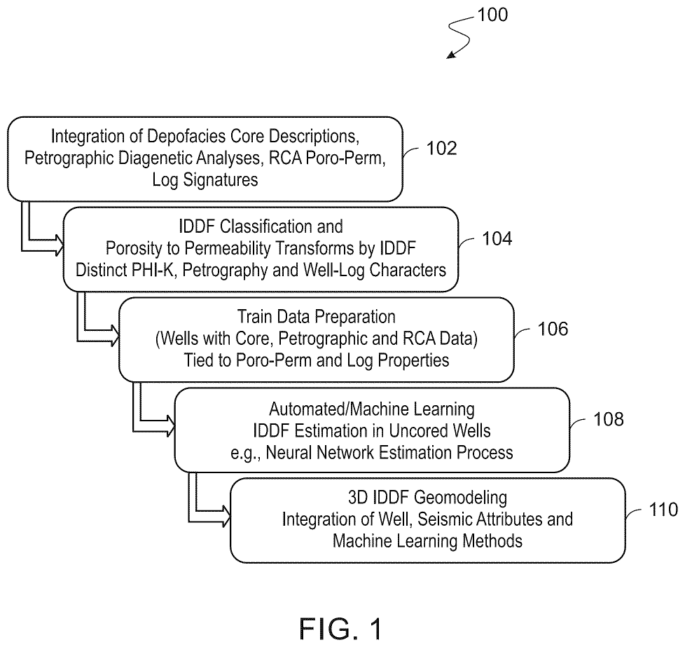

FIG. 1 is a flow chart showing an example of a workflow 100 for integrated diagenetic-depositional facies (IDDF) characterization and 3D geomodeling, according to some implementations of the present disclosure.

At 102, integration occurs that integrates depofacies core descriptions, petrographic diagenetic analyses, RCA poro-perm, and log signatures. For example, the workflow 100 can start with an integration of RCA results (e.g., porosity and permeability) into a similar 1D well-section template with the well-log signatures in seismic-to-simulation application (e.g., Petrel) (e.g., gamma ray, density, neutron, resistivity, sonic, total porosity, estimated permeability, and limestone-dolomite multi-mineral logs), core litho-facies description flags, borehole formation image logs, cumulative oil/gas production flow logs and flow rate logs, and 1D seismic attribute logs. The workflow 100 can use a computer-based database that consists of petrographic descriptions, analysis, and thin section photos that are compiled by depth. Each petrographic sample corresponds to an RCA data point in the seismic-to-simulation application (e.g., Petrel) well-section window.

At 104, IDDF classification occurs including porosity to permeability transforms by IDDF, distinct PHI-K, petrography, and well-log characteristics. For example, step 104 includes the classification of the IDDF using several genetic and analytic criteria: 1) distinctive RCA porosity to permeability cross-plots and transforms; 2) typical well-log values, cross-plots, and signatures; 3) certain depo-facies textural classes based on whole-core descriptions; 4) genetic petrographic criteria such as dominant pore type, grain type, and variation; and 5) distinct diagenetic characters in thin sections such as dominant mineral, dissolution, dolomitization, micritization, and cementation features. All of these inter-connected criteria become the basis of the IDDF classification that is subsequently translated into discrete flags in seismic-to-simulation application (e.g., Petrel) well-section window. In order to improve the classification, the discrete flags are also used as the color-fill for each of the well-log signatures.

At 106, training data is prepared, including wells with core, petrographic, and RCA data, tied to poro-perm and log properties. For example, all of the IDDF flags can be utilized as training data for a machine learning process in a seismic-to-simulation application (e.g., Petrel), e.g., a “Neural Network Train Estimation Model” function. An important step in the training data preparation is to fine-tune the IDDF flags to honor well-log shoulder-bed effects and depth-gaps between core and well-log data. This process can be done iteratively by running the Neural Network Train Estimation Modeling on wells with complete data-sets, such as: RCA, petrographic analysis, basic well-logs, and core data. Once consistent results are achieved between input IDDF training data and output IDDF neural network estimation, then the training data (IDDF flags) in a particular well can be stored in a final IDDF training dataset.

At 108, automated/machine learning occurs, including IDDF estimation in un-cored wells, e.g., including neural network estimation processes. For example, a machine learning process (e.g. Petrel neural network estimation or other artificial intelligence processes) can be run in wells with no core and petrographic data. This particular step utilizes final and clean IDDF training data as input, and estimates the IDDF flags based on well-log values (e.g., density, neutron, gamma ray, sonic, and resistivity) and correlation in each IDDF class.

At 110, 3D IDDF geomodeling occurs, including integration of well, seismic attributes, and machine learning methods. For example, all IDDF inputs both from wells with petrographic data (IDDF training data) and wells without core data (e.g., machine-learning estimated IDDF) are then used as input for up-scaling process into 3D geo-cellular grids. This process can be done by running a seismic-to-simulation application (e.g., Petrel) “scale-up well logs” function, either using a “mid-point pick” or a “most-of” averaging method. Sample selection can be done by treating the IDDF log “as-lines,” with either a “simple” or “neighbor cell” grid selection method. These particular steps transform the IDDF flag logs into 3D geo-cellular grids.

Another approach in the workflow includes linking the up-scaled IDDF flags (e.g., IDDF geo-cellular grids) with seismic data. This process can be done using several different seismic data-sets, depending on the availability and resolution of the seismic data. The following processes describe IDDF to seismic integration methods using seismic acoustic impedance and quadrature-phase attribute extraction. Intervals with more diagenetic dissolutions that yield higher porosity (e.g., dissolutions-related IDDF classes) correspond to low seismic acoustic impedance geobodies. By comparison, intervals with more dolomitization, cementation, and dominant micrite occurrence that yield lower porosity correspond to high seismic acoustic impedance geobodies. Several sets of seismic-based IDDF probability geobodies are extracted from a seismic impedance volume.

In several study cases, seismic acoustic impedance cubes are not always available, hence one of the inventions here is to use the “Seismic Quadrature Phase Seismic Extraction” based on basic a “Pre-Stack Seismic Volume” to guide IDDF distribution. This particular process can start by converting basic zero-phase seismic cubes to quadrature amplitude phase attributes in seismic-to-simulation software (e.g., Petrel) “Volume Attributes” process. The zero-phase seismic cube can be utilized as input data in the “Volume Attributes” process. “Quadrature amplitude” can be used as the calculation method in the seismic-to-simulation software. A new seismic quadrature phase cube can be generated as the output of this process. The result can then be subsequently used to extract mean, maximum, and minimum amplitude seismic attributes in the seismic-to-simulation software (e.g., Petrel) surface attribute process. These attributes tie consistently with the 1D IDDF flags, e.g., higher amplitudes correspond to dominant dissolution-related IDDFs and lower amplitudes tied to lower reservoir quality IDDFs.

Another step in seismic and IDDF integration is to overlay the extracted quad-phase amplitude with the top of the reservoir structure map. In a late burial diagenetic dissolution setting, dissolution patterns would correspond to the proximity of the structural crest. These dissolution patterns are well-represented by the quadrature phase amplitude attribute that occur within the proximity of the crestal area. This integration step ensures that IDDF distribution proxies (e.g., 1D IDDF flags and quad-phase attributes) honor hydro-geochemical diagenetic processes and experiments.

The 3D IDDF geo-cellular modeling workflow can utilize a facies modeling process in seismic-to-simulation software (e.g., Petrel). Up-scaled IDDF flags (e.g., 3D geo-cellular grids within wells) can be used as the basis for the facies modeling process using, for example, a sequential indicator simulation (SIS) algorithm. Prior to a model run, the IDDF flags can be analyzed using seismic-to-simulation software (e.g., Petrel) data analysis to generate vertical proportion curves (VPC) for each IDDF class and to define experimental variogram ranges and azimuths. Major, minor, and vertical variogram ranges should be consistent with the analogous diagenetic concepts and experiments, as well as with the seismic attribute geometries. These datasets can serve as the primary input for 3D IDDF distribution and modeling. Seismic attributes (e.g., acoustic impedance or quad-phase amplitude) can be used as secondary probability trend, e.g., to guide IDDF probability occurrence spatially beyond well controls.

The subsequent process is to populate the 3D IDDF property model with Porosity, Permeability, and Water Saturation (S_{w}) functions in each IDDF class. Porosity logs are first up-scaled into the 3D geo-cellular grids. Porosity histograms in each IDDF class can be defined, and each set of the histograms can be utilized as input for 3D porosity modeling under a “Petrophysical Modeling” process. Porosity to permeability transforms of each IDDF class are also established. These transforms can be generated by integrating and characterizing petrographic analyses, routine core analyses (e.g., including whole core and CT scan/image analysis for larger pore sizes), and basic-well logs into genetically-related porosity to permeability cross plots by IDDF classes. A 3D permeability model can then be generated by transforming a previously-generated 3D porosity model into permeability values in each IDDF class.

A set of functions that include key parameters such as porosity, permeability, capillary pressure, and R-constant can be employed to generate a 3D S_{w} model. The process can utilize IDDF-based porosity and permeability models that have been generated in the previous step. As a result, S_{w} distribution can be controlled by the IDDF distribution. A 3D S_{w} model can be constructed using a combination of rock specific matrix capillary and vugular zero capillary pressure. Eventually, each of the S_{w}-Pc or zero Pc functions can be applied into each of the 3D cells to generate the final 3D S_{w} model.

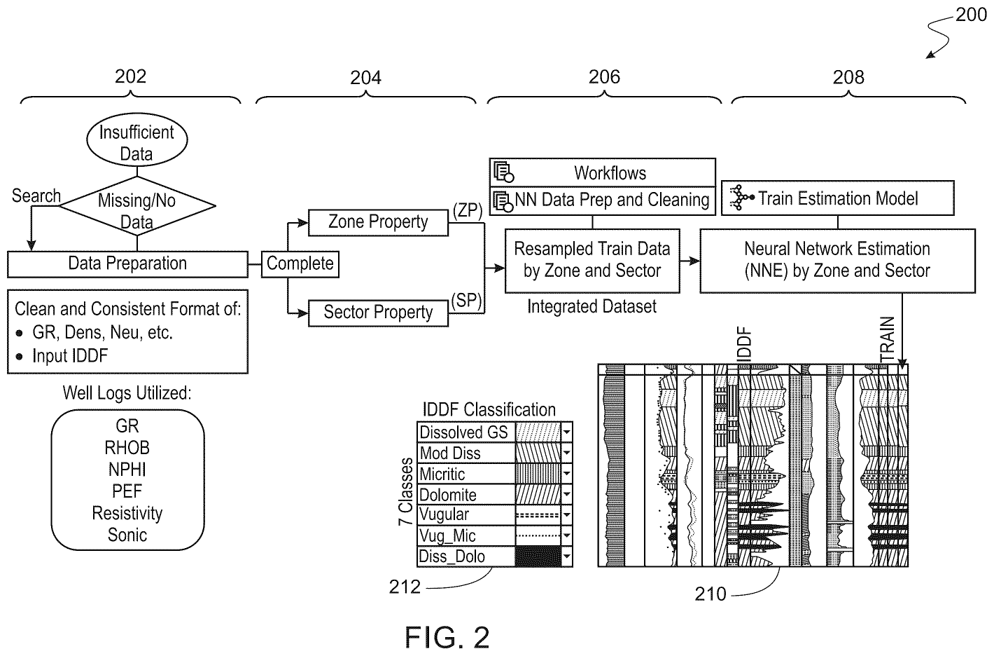

FIG. 2 is a block diagram showing an example workflow 200 for well data preparation, integration, and machine learning estimation of the IDDF, according to some implementations of the present disclosure. In a data preparation step 202, clean and consistent formats are determined for gamma ray (GR), density (dens), neutron (neu), and input IDDF logs. The data preparation step 202 can use information from various logs, including GR logs, RHOB logs, NPHI logs, PEF, resistivity logs, and sonic logs. The data preparation step 202 can search for missing data.

A property filtering step 204 can be used to determine zone properties (ZP) and sector properties (SP). In a data sampling step 206, training data can be sampled by zone and sector.

In a machine learning step 208, an estimation model can be trained, and neural network estimation (NNE) can be estimated by zone and sector. Outputs include various estimated IDDF logs and plots 210 at multiple wells within the zone, sector and IDDF classifications 212.

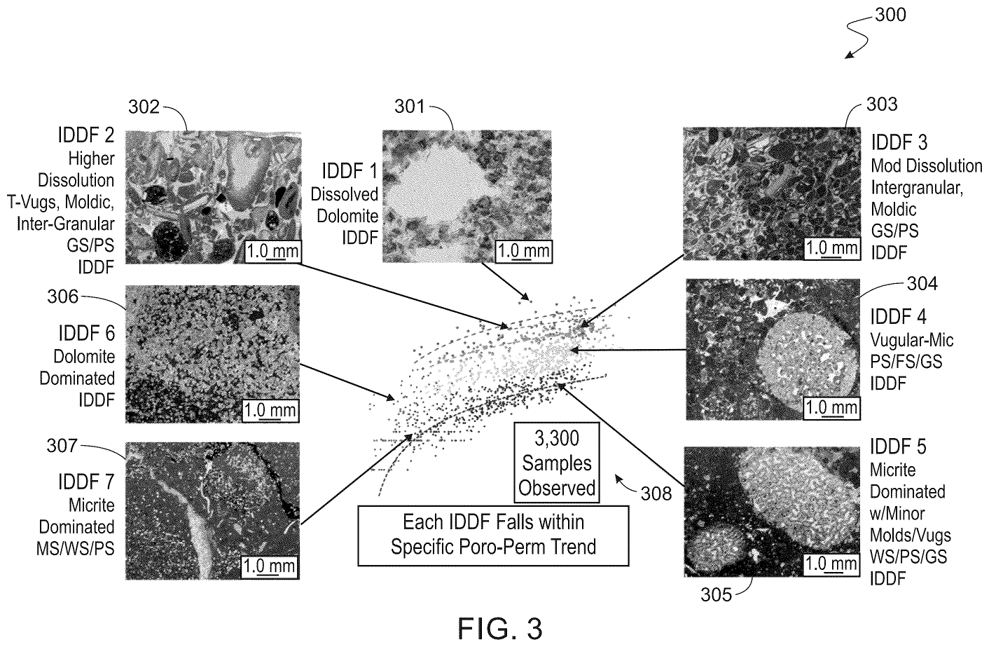

FIG. 3 is a block diagram showing an example of an IDDF classification 300 using the integration of petrography and routine core (porosity and permeability) analyses, according to some implementations of the present disclosure. Results of the IDDF classification 300 include IDDFs 301-307 that are generated from 3,300 samples 308, where each IDDF falls within a specific poro-perm trend and represents specific IDDF class.

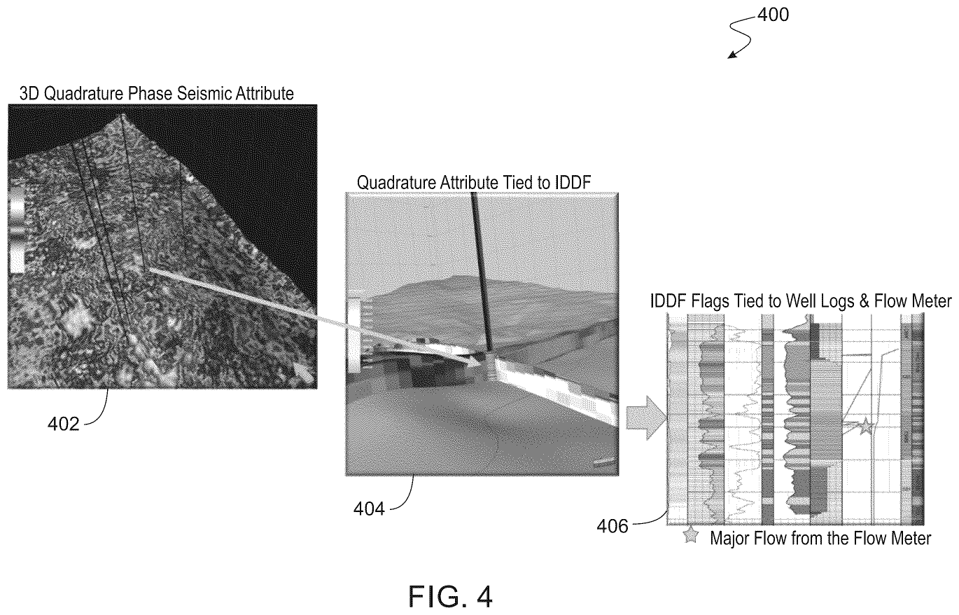

FIG. 4 is a flow diagram showing an example integration 400 of seismic data, well logs, flow meter data, and the IDDF flags at well location, according to some implementations of the present disclosure. The integration 400 begins with 3D quadrature phase seismic attributes 402, from which associations 404 include quadrature attributes tied to the IDDF. From there, corresponding IDDF flags 406 are tied to well logs (e.g., gamma ray, porosity, permeability, and density logs) and a production flow meter log.

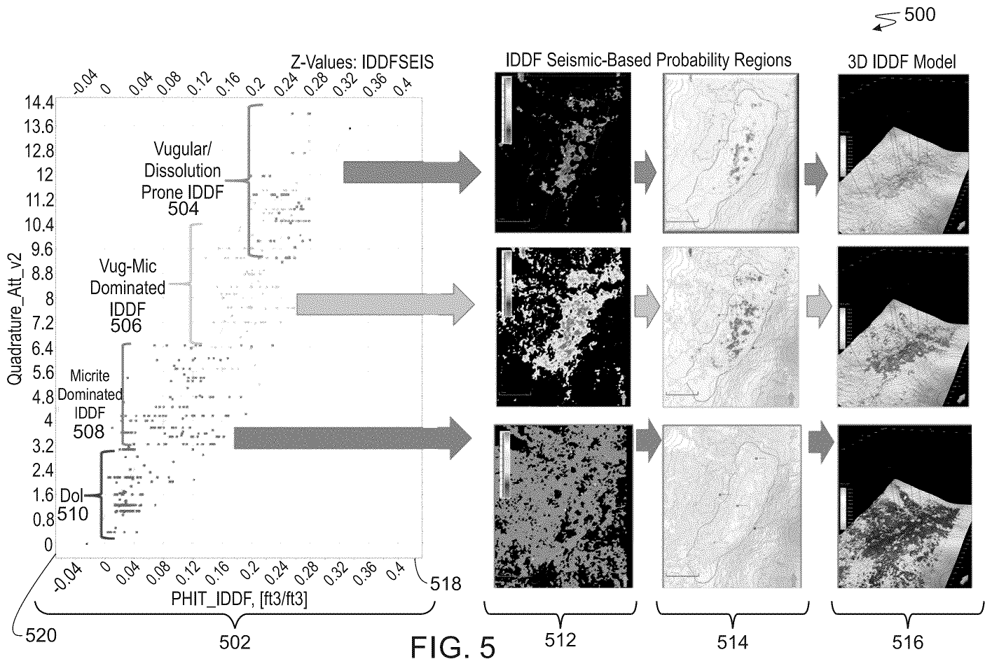

FIG. 5 is a flow diagram showing an example of 3D IDDF modeling 500 using an integration of seismic and well data, according to some implementations of the present disclosure. Input plots 502 that are inputs to the 3D IDDF modeling 500 include a vugular dissolution prone IDDF 504, a vugular-micrite (vug-mic) dominated IDDF 506, a micrite dominated IDDF 508, and a dolomite (dol) IDDF 510. The input plots 502 are plotted relative to porosity axis 518 and quadrature amplitude attribute axis 520. The input plots 502 serve as inputs to identification of corresponding IDDF seismic-based probability regions, first as regions 512 and then regions 514, which are inputs to the 3D IDDF model 516.

Workflows that can be supported or implemented using the techniques of the present disclosure include: 1) a workflow for IDDF characterization and 3D geologic modeling; 2) a method to integrate and display multi-disciplinary data for IDDF characterization; 3) a method and criteria (e.g., genetic and analytic criteria) for IDDF classification; 4) a method to prepare training data for IDDF estimation in un-cored wells; 5) a method to estimate IDDFs utilizing machine learning (e.g., neural network) process; 6) a method to link and extract the IDDF probability trend from a seismic acoustic impedance volume; 7) a method to link and extract the IDDF probability trend from a quadrature seismic attribute; 8) a method to integrate the IDDF flags with the seismic data; 9) a method to populate the IDDF distribution into 3D geo-cellular grids using sequential indicator simulation algorithm; 10) a method to generate 3D porosity model by IDDF classes; 11) a method to generate IDDF porosity-to-permeability transforms; 12) a method to populate IDDF-based 3D permeability model; and 13) a method to generate 3D water saturation model based on IDDF-related properties.

Experimentation using IDDF characterization and 3D geomodeling was conducted in a carbonate oil field. The experimentation included multi-disciplinary datasets, both static and dynamic, integrated into a 3D geo-cellular modeling platform, resulting in multiple observations. IDDF proportions in certain reservoir intervals may be higher or lower than predictions due to data uncertainty. The geometry of IDDF distribution in the 3D volume might be smaller or larger than the model due to statistical and seismic data quality uncertainty. IDDF-based porosity may be lower or higher than predicted values due to data uncertainty and resolution. IDDF-based permeability may be lower or higher than predicted values due to data uncertainty and resolution.

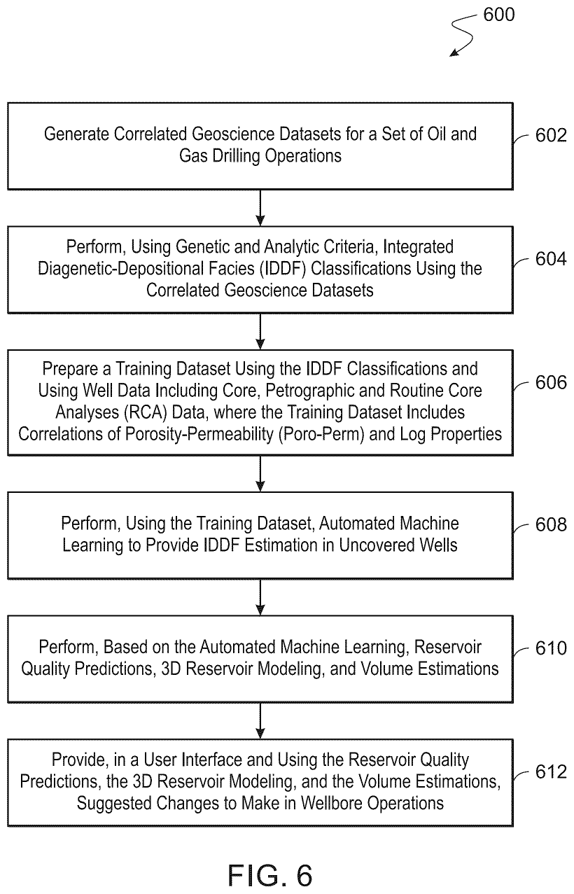

FIG. 6 is a flowchart of an example of a method 600 for determining reservoir quality, according to some implementations of the present disclosure. For clarity of presentation, the description that follows generally describes method 600 in the context of the other figures in this description. However, it will be understood that method 600 can be performed, for example, by any suitable system, environment, software, and hardware, or a combination of systems, environments, software, and hardware, as appropriate. In some implementations, various steps of method 600 can be run in parallel, in combination, in loops, or in any order.

At 602, correlated geoscience datasets are generated for a set of oil and gas drilling operations. As an example, generating the correlated geoscience datasets can include linking petrographic thin sections analyses with scales of data from core descriptions, well log signatures, RCA, borehole image logs interpretation, production logging tool (PLT) flow meter signals, diagenetic proxies, and depositional concepts. From 602, method 600 proceeds to 604. At 604, IDDF classifications are performed using genetic and analytic criteria and using the correlated geoscience datasets. For example, performing the IDDF classification can include performing porosity to permeability transforms of each IDDF class. From 604, method 600 proceeds to 606.

At 606, a training dataset is prepared using the IDDF classifications and using well data including core, petrographic, and routine core analyses (RCA) data. The training dataset includes correlations of porosity-permeability (poro-perm) and log properties. In some implementations, preparing the training dataset can include fine-tuning IDDF flags to honor well-log shoulder-bed effects and depth-gaps between core and well-log data. From 606, method 600 proceeds to 608.

At 608, automated machine learning is performed using the training dataset to provide IDDF estimation in uncovered wells. For example, performing the automated machine learning can include running machine learning in wells with no core and petrographic data using final and clean IDDF training data as input. IDDF flags can be estimated based on well-log values, including density, neutron, gamma ray, sonic, and resistivity, and using correlations in each IDDF class. From 608, method 600 proceeds to 610.

At 610, reservoir quality predictions, 3D reservoir modeling, and volume estimations are performed based on the automated machine learning. From 610, method 600 proceeds to 612.

At 612, suggested changes to make in wellbore operations are provided in a user interface based on the reservoir quality predictions, the 3D reservoir modeling, and the volume estimations. For example, making changes in wellbore operations includes providing inputs to change parameters of equipment used in drilling. After 612, method 600 can stop.

In some implementations, in addition to (or in combination with) any previously-described features, techniques of the present disclosure can include the following. Customized user interfaces can present intermediate or final results of the above described processes to a user. The presented information can be presented in one or more textual, tabular, or graphical formats, such as through a dashboard. The information can be presented at one or more on-site locations (such as at an oil well or other facility), on the Internet (such as on a webpage), on a mobile application (or “app”), or at a central processing facility. The presented information can include suggestions, such as suggested changes in parameters or processing inputs, that the user can select to implement improvements in a production environment, such as in the exploration, production, and/or testing of petrochemical processes or facilities. For example, the suggestions can include parameters that, when selected by the user, can cause a change or an improvement in drilling parameters (including speed and direction) or overall production of a gas or oil well. The suggestions, when implemented by the user, can improve the speed and accuracy of calculations, streamline processes, improve models, and solve problems related to efficiency, performance, safety, reliability, costs, downtime, and the need for human interaction. In some implementations, the suggestions can be implemented in real-time, such as to provide an immediate or near-immediate change in operations or in a model. The term real-time can correspond, for example, to events that occur within a specified period of time, such as within one minute or within one second. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart or are located in different countries or other jurisdictions.

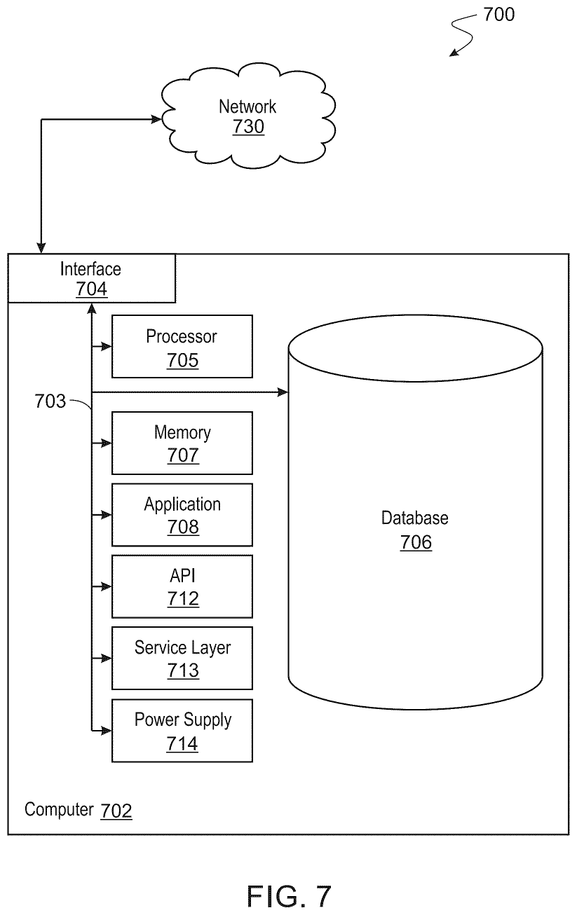

FIG. 7 is a block diagram of an example computer system 700 used to provide computational functionalities associated with described algorithms, methods, functions, processes, flows, and procedures described in the present disclosure, according to some implementations of the present disclosure. The illustrated computer 702 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 702 can include input devices such as keypads, keyboards, and touch screens that can accept user information. Also, the computer 702 can include output devices that can convey information associated with the operation of the computer 702. The information can include digital data, visual data, audio information, or a combination of information. The information can be presented in a graphical user interface (UI) (or GUI).

The computer 702 can serve in a role as a client, a network component, a server, a database, a persistency, or components of a computer system for performing the subject matter described in the present disclosure. The illustrated computer 702 is communicably coupled with a network 730. In some implementations, one or more components of the computer 702 can be configured to operate within different environments, including cloud-computing-based environments, local environments, global environments, and combinations of environments.

At a top level, the computer 702 is an electronic computing device operable to receive, transmit, process, store, and manage data and information associated with the described subject matter. According to some implementations, the computer 702 can also include, or be communicably coupled with, an application server, an email server, a web server, a caching server, a streaming data server, or a combination of servers.

The computer 702 can receive requests over network 730 from a client application (for example, executing on another computer 702). The computer 702 can respond to the received requests by processing the received requests using software applications. Requests can also be sent to the computer 702 from internal users (for example, from a command console), external (or third) parties, automated applications, entities, individuals, systems, and computers.

Each of the components of the computer 702 can communicate using a system bus 703. In some implementations, any or all of the components of the computer 702, including hardware or software components, can interface with each other or the interface 704 (or a combination of both) over the system bus 703. Interfaces can use an application programming interface (API) 712, a service layer 713, or a combination of the API 712 and service layer 713. The API 712 can include specifications for routines, data structures, and object classes. The API 712 can be either computer-language independent or dependent. The API 712 can refer to a complete interface, a single function, or a set of APIs.

The service layer 713 can provide software services to the computer 702 and other components (whether illustrated or not) that are communicably coupled to the computer 702. The functionality of the computer 702 can be accessible for all service consumers using this service layer. Software services, such as those provided by the service layer 713, can provide reusable, defined functionalities through a defined interface. For example, the interface can be software written in JAVA, C++, or a language providing data in extensible markup language (XML) format. While illustrated as an integrated component of the computer 702, in alternative implementations, the API 712 or the service layer 713 can be stand-alone components in relation to other components of the computer 702 and other components communicably coupled to the computer 702. Moreover, any or all parts of the API 712 or the service layer 713 can be implemented as child or sub-modules of another software module, enterprise application, or hardware module without departing from the scope of the present disclosure.

The computer 702 includes an interface 704. Although illustrated as a single interface 704 in FIG. 7, two or more interfaces 704 can be used according to particular needs, desires, or particular implementations of the computer 702 and the described functionality. The interface 704 can be used by the computer 702 for communicating with other systems that are connected to the network 730 (whether illustrated or not) in a distributed environment. Generally, the interface 704 can include, or be implemented using, logic encoded in software or hardware (or a combination of software and hardware) operable to communicate with the network 730. More specifically, the interface 704 can include software supporting one or more communication protocols associated with communications. As such, the network 730 or the interface's hardware can be operable to communicate physical signals within and outside of the illustrated computer 702.

The computer 702 includes a processor 705. Although illustrated as a single processor 705 in FIG. 7, two or more processors 705 can be used according to particular needs, desires, or particular implementations of the computer 702 and the described functionality. Generally, the processor 705 can execute instructions and can manipulate data to perform the operations of the computer 702, including operations using algorithms, methods, functions, processes, flows, and procedures as described in the present disclosure.

The computer 702 also includes a database 706 that can hold data for the computer 702 and other components connected to the network 730 (whether illustrated or not). For example, database 706 can be an in-memory, conventional, or a database storing data consistent with the present disclosure. In some implementations, database 706 can be a combination of two or more different database types (for example, hybrid in-memory and conventional databases) according to particular needs, desires, or particular implementations of the computer 702 and the described functionality. Although illustrated as a single database 706 in FIG. 7, two or more databases (of the same, different, or combination of types) can be used according to particular needs, desires, or particular implementations of the computer 702 and the described functionality. While database 706 is illustrated as an internal component of the computer 702, in alternative implementations, database 706 can be external to the computer 702.

The computer 702 also includes a memory 707 that can hold data for the computer 702 or a combination of components connected to the network 730 (whether illustrated or not). Memory 707 can store any data consistent with the present disclosure. In some implementations, memory 707 can be a combination of two or more different types of memory (for example, a combination of semiconductor and magnetic storage) according to particular needs, desires, or particular implementations of the computer 702 and the described functionality. Although illustrated as a single memory 707 in FIG. 7, two or more memories 707 (of the same, different, or combination of types) can be used according to particular needs, desires, or particular implementations of the computer 702 and the described functionality. While memory 707 is illustrated as an internal component of the computer 702, in alternative implementations, memory 707 can be external to the computer 702.

The application 708 can be an algorithmic software engine providing functionality according to particular needs, desires, or particular implementations of the computer 702 and the described functionality. For example, application 708 can serve as one or more components, modules, or applications. Further, although illustrated as a single application 708, the application 708 can be implemented as multiple applications 708 on the computer 702. In addition, although illustrated as internal to the computer 702, in alternative implementations, the application 708 can be external to the computer 702.

The computer 702 can also include a power supply 714. The power supply 714 can include a rechargeable or non-rechargeable battery that can be configured to be either user- or non-user-replaceable. In some implementations, the power supply 714 can include power-conversion and management circuits, including recharging, standby, and power management functionalities. In some implementations, the power supply 714 can include a power plug to allow the computer 702 to be plugged into a wall socket or a power source to, for example, power the computer 702 or recharge a rechargeable battery.

There can be any number of computers 702 associated with, or external to, a computer system containing computer 702, with each computer 702 communicating over network 730. Further, the terms “client,” “user,” and other appropriate terminology can be used interchangeably, as appropriate, without departing from the scope of the present disclosure. Moreover, the present disclosure contemplates that many users can use one computer 702 and one user can use multiple computers 702.

Described implementations of the subject matter can include one or more features, alone or in combination.

For example, in a first implementation, a computer-implemented method includes the following. Correlated geoscience datasets are generated for a set of oil and gas drilling operations. Integrated Diagenetic-Depositional Facies (IDDF) classifications are performed using genetic and analytic criteria and using the correlated geoscience datasets. A training dataset is prepared using the IDDF classifications and well data including core, petrographic, and routine core analyses (RCA) data. The training dataset includes correlations of porosity-permeability (poro-perm) and log properties. Automated machine learning is performed using the training dataset to provide IDDF estimation in uncovered wells. Reservoir quality predictions, 3D reservoir modeling, and volume estimations are performed based on the automated machine learning. Suggested changes to make in wellbore operations are provided in a user interface based on the reservoir quality predictions, the 3D reservoir modeling, and the volume estimations.

The foregoing and other described implementations can each, optionally, include one or more of the following features:

A first feature, combinable with any of the following features, where generating the correlated geoscience datasets includes linking petrographic thin sections analyses with scales of data from core descriptions, well log signatures, RCA, borehole image logs interpretation, production logging tool (PLT) flow meter signals, diagenetic proxies and depositional concepts.

A second feature, combinable with any of the previous or following features, where performing the IDDF classification includes performing porosity to permeability transforms of each IDDF class.

A third feature, combinable with any of the previous or following features, where making changes in wellbore operations includes providing inputs to change parameters of equipment used in drilling.

A fourth feature, combinable with any of the previous or following features, where preparing the training dataset includes fine-tuning IDDF flags to honor well-log shoulder-bed effects and depth-gaps between core and well-log data.

A fifth feature, combinable with any of the previous or following features, where performing the automated machine learning includes running machine learning in wells with no core and petrographic data using final and clean IDDF training data as input.

A sixth feature, combinable with any of the previous or following features, the method further including estimating IDDF flags based on well-log values, including density, neutron, gamma ray, sonic, and resistivity, and using correlations in each IDDF class.

In a second implementation, a non-transitory, computer-readable medium stores one or more instructions executable by a computer system to perform operations including the following. Correlated geoscience datasets are generated for a set of oil and gas drilling operations. Integrated Diagenetic-Depositional Facies (IDDF) classifications are performed using genetic and analytic criteria and using the correlated geoscience datasets. A training dataset is prepared using the IDDF classifications and well data including core, petrographic, and routine core analyses (RCA) data. The training dataset includes correlations of porosity-permeability (poro-perm) and log properties. Automated machine learning is performed using the training dataset to provide IDDF estimation in uncovered wells. Reservoir quality predictions, 3D reservoir modeling, and volume estimations are performed based on the automated machine learning. Suggested changes to make in wellbore operations are provided in a user interface based on the reservoir quality predictions, the 3D reservoir modeling, and the volume estimations.

The foregoing and other described implementations can each, optionally, include one or more of the following features:

A first feature, combinable with any of the following features, where generating the correlated geoscience datasets includes linking petrographic thin sections analyses with scales of data from core descriptions, well log signatures, RCA, borehole image logs interpretation, production logging tool (PLT) flow meter signals, diagenetic proxies and depositional concepts.

A second feature, combinable with any of the previous or following features, where performing the IDDF classification includes performing porosity to permeability transforms of each IDDF class.

A third feature, combinable with any of the previous or following features, where making changes in wellbore operations includes providing inputs to change parameters of equipment used in drilling.

A fourth feature, combinable with any of the previous or following features, where preparing the training dataset includes fine-tuning IDDF flags to honor well-log shoulder-bed effects and depth-gaps between core and well-log data.

A fifth feature, combinable with any of the previous or following features, where performing the automated machine learning includes running machine learning in wells with no core and petrographic data using final and clean IDDF training data as input.

A sixth feature, combinable with any of the previous or following features, the method further including estimating IDDF flags based on well-log values, including density, neutron, gamma ray, sonic, and resistivity, and using correlations in each IDDF class.

In a third implementation, a computer-implemented system includes one or more processors and a non-transitory computer-readable storage medium coupled to the one or more processors and storing programming instructions for execution by the one or more processors. The programming instructions instruct the one or more processors to perform operations including the following. Correlated geoscience datasets are generated for a set of oil and gas drilling operations. Integrated Diagenetic-Depositional Facies (IDDF) classifications are performed using genetic and analytic criteria and using the correlated geoscience datasets. A training dataset is prepared using the IDDF classifications and well data including core, petrographic, and routine core analyses (RCA) data. The training dataset includes correlations of porosity-permeability (poro-perm) and log properties. Automated machine learning is performed using the training dataset to provide IDDF estimation in uncovered wells. Reservoir quality predictions, 3D reservoir modeling, and volume estimations are performed based on the automated machine learning. Suggested changes to make in wellbore operations are provided in a user interface based on the reservoir quality predictions, the 3D reservoir modeling, and the volume estimations.

The foregoing and other described implementations can each, optionally, include one or more of the following features:

A first feature, combinable with any of the following features, where generating the correlated geoscience datasets includes linking petrographic thin sections analyses with scales of data from core descriptions, well log signatures, RCA, borehole image logs interpretation, production logging tool (PLT) flow meter signals, diagenetic proxies and depositional concepts.

A second feature, combinable with any of the previous or following features, where performing the IDDF classification includes performing porosity to permeability transforms of each IDDF class.

A third feature, combinable with any of the previous or following features, where making changes in wellbore operations includes providing inputs to change parameters of equipment used in drilling.

A fourth feature, combinable with any of the previous or following features, where preparing the training dataset includes fine-tuning IDDF flags to honor well-log shoulder-bed effects and depth-gaps between core and well-log data.

A fifth feature, combinable with any of the previous or following features, where performing the automated machine learning includes running machine learning in wells with no core and petrographic data using final and clean IDDF training data as input.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field-programmable gate array (FPGA), or an application-specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub-programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory.

Graphics processing units (GPUs) can also be used in combination with CPUs. The GPUs can provide specialized processing that occurs in parallel to processing performed by CPUs. The specialized processing can include artificial intelligence (AI) applications and processing, for example. GPUs can be used in GPU clusters or in multi-GPU computing.

A computer can include, or be operatively coupled to, one or more mass storage devices for storing data. In some implementations, a computer can receive data from, and transfer data to, the mass storage devices including, for example, magnetic, magneto-optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer-readable media (transitory or non-transitory, as appropriate) suitable for storing computer program instructions and data can include all forms of permanent/non-permanent and volatile/non-volatile memory, media, and memory devices. Computer-readable media can include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer-readable media can also include, for example, magnetic devices such as tape, cartridges, cassettes, and internal/removable disks. Computer-readable media can also include magneto-optical disks and optical memory devices and technologies including, for example, digital video disc (DVD), CD-ROM, DVD+/−R, DVD-RAM, DVD-ROM, HD-DVD, and BLU-RAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated into, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that the user uses. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch-screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at the application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

What is claimed is:

1. A computer-implemented method, comprising:
generating correlated geoscience datasets for a set of oil and gas drilling operations;
performing, using genetic and analytic criteria, Integrated Diagenetic-Depositional Facies (IDDF) classifications using the correlated geoscience datasets;
preparing a training dataset using the IDDF classifications and using well data including core, petrographic and routine core analyses (RCA) data, wherein the training dataset includes correlations of porosity-permeability (poro-perm) and log properties;
performing, using the training dataset, automated machine learning to provide IDDF estimation in uncovered wells;
performing, based on the automated machine learning, reservoir quality predictions, three-dimensional (3D) reservoir modeling, and volume estimations; and
providing, in a user interface and using the reservoir quality predictions, the 3D reservoir modeling, and the volume estimations, suggested changes to make in wellbore operations.

2. The computer-implemented method of claim 1, wherein generating the correlated geoscience datasets includes linking petrographic thin sections analyses with scales of data from core descriptions, well log signatures, RCA, borehole image logs interpretation, production logging tool (PLT) flow meter signals, diagenetic proxies and depositional concepts.

3. The computer-implemented method of claim 1, wherein performing the IDDF classification includes performing porosity to permeability transforms of each IDDF class.

4. The computer-implemented method of claim 1, wherein making changes in wellbore operations includes providing inputs to change parameters of equipment used in drilling.

5. The computer-implemented method of claim 1, wherein preparing the training dataset includes fine-tuning IDDF flags to honor well-log shoulder-bed effects and depth-gaps between core and well-log data.

6. The computer-implemented method of claim 1, wherein performing the automated machine learning includes running machine learning in wells with no core and petrographic data using final and clean IDDF training data as input.

7. The computer-implemented method of claim 6, further comprising estimating IDDF flags based on well-log values, including density, neutron, gamma ray, sonic, and resistivity, and using correlations in each IDDF class.

8. A non-transitory, computer-readable medium storing one or more instructions executable by a computer system to perform operations comprising:
generating correlated geoscience datasets for a set of oil and gas drilling operations;
performing, using genetic and analytic criteria, Integrated Diagenetic-Depositional Facies (IDDF) classifications using the correlated geoscience datasets;
preparing a training dataset using the IDDF classifications and using well data including core, petrographic and routine core analyses (RCA) data, wherein the training dataset includes correlations of porosity-permeability (poro-perm) and log properties;
performing, using the training dataset, automated machine learning to provide IDDF estimation in uncovered wells;
performing, based on the automated machine learning, reservoir quality predictions, three-dimensional (3D) reservoir modeling, and volume estimations; and
providing, in a user interface and using the reservoir quality predictions, the 3D reservoir modeling, and the volume estimations, suggested changes to make in wellbore operations.

9. The non-transitory, computer-readable medium of claim 8, wherein generating the correlated geoscience datasets includes linking petrographic thin sections analyses with scales of data from core descriptions, well log signatures, RCA, borehole image logs interpretation, production logging tool (PLT) flow meter signals, diagenetic proxies and depositional concepts.

10. The non-transitory, computer-readable medium of claim 8, wherein performing the IDDF classification includes performing porosity to permeability transforms of each IDDF class.

11. The non-transitory, computer-readable medium of claim 8, wherein making changes in wellbore operations includes providing inputs to change parameters of equipment used in drilling.

12. The non-transitory, computer-readable medium of claim 8, wherein preparing the training dataset includes fine-tuning IDDF flags to honor well-log shoulder-bed effects and depth-gaps between core and well-log data.

13. The non-transitory, computer-readable medium of claim 8, wherein performing the automated machine learning includes running machine learning in wells with no core and petrographic data using final and clean IDDF training data as input.

14. The non-transitory, computer-readable medium of claim 13, the operations further comprising estimating IDDF flags based on well-log values, including density, neutron, gamma ray, sonic, and resistivity, and using correlations in each IDDF class.

15. A computer-implemented system, comprising:
one or more processors; and
a non-transitory computer-readable storage medium coupled to the one or more processors and storing programming instructions for execution by the one or more processors, the programming instructions instructing the one or more processors to perform operations comprising:
generating correlated geoscience datasets for a set of oil and gas drilling operations;
performing, using genetic and analytic criteria, Integrated Diagenetic-Depositional Facies (IDDF) classifications using the correlated geoscience datasets;
preparing a training dataset using the IDDF classifications and using well data including core, petrographic and routine core analyses (RCA) data, wherein the training dataset includes correlations of porosity-permeability (poro-perm) and log properties;
performing, using the training dataset, automated machine learning to provide IDDF estimation in uncovered wells;
performing, based on the automated machine learning, reservoir quality predictions, three-dimensional (3D) reservoir modeling, and volume estimations; and
providing, in a user interface and using the reservoir quality predictions, the 3D reservoir modeling, and the volume estimations, suggested changes to make in wellbore operations.

16. The computer-implemented system of claim 15, wherein generating the correlated geoscience datasets includes linking petrographic thin sections analyses with scales of data from core descriptions, well log signatures, RCA, borehole image logs interpretation, production logging tool (PLT) flow meter signals, diagenetic proxies and depositional concepts.

17. The computer-implemented system of claim 15, wherein performing the IDDF classification includes performing porosity to permeability transforms of each IDDF class.

18. The computer-implemented system of claim 15, wherein making changes in wellbore operations includes providing inputs to change parameters of equipment used in drilling.

19. The computer-implemented system of claim 15, wherein preparing the training dataset includes fine-tuning IDDF flags to honor well-log shoulder-bed effects and depth-gaps between core and well-log data.

20. The computer-implemented system of claim 15, wherein performing the automated machine learning includes running machine learning in wells with no core and petrographic data using final and clean IDDF training data as input.
